(19) United States
(12) Patent Application Publication
(10) Pub. No.: US 2020/0213486 A1
(43) Pub. Date: Jul. 2, 2020

(54) VEHICLE CAMERA SYSTEM AND METHOD

(71) Applicants: CHONGQING JINKANG NEW ENERGY VEHICLE CO., LTD., Chongqing (CN); SF MOTORS, INC., Santa Clara, CA (US)

(72) Inventors: Peicong Liu, San Lorenzo, CA (US); Chen Bao, Daly City, CA (US); Avery Jutkowitz, Pleasanton, CA (US); Liu He, San Jose, CA (US)

(21) Appl. No.: 16/233,565

(22) Filed: Dec. 27, 2018

(51) Int. Cl. H04N 5/225; H01L 27/146; B60R 1/00

(52) U.S. Cl. CPC H04N 5/2254; H04N 5/2256; H04N 5/2252; B60R 2300/103; H01L 27/1462; B60R 1/00; H01L 27/14649

(57) ABSTRACT

A system for capturing and processing an image in a camera system for a vehicle includes a camera module with a lens and a sensor, an image signal processor, a control unit, and an infrared elimination mechanism. The system may include at least one infrared illuminator. In normal light conditions, the infrared portion of the light is not used. The system may include an IR-cut filter disposed within the camera module that is moveable between a filtered position where infrared light is blocked before reaching an RGB sensor in normal light conditions and an unfiltered position where all of the light reaches the RGB sensor in low light conditions. The system may include an RGB-IR sensor without a filter, and the infrared portion captured at the sensor is ignored in normal light conditions and, in low light conditions, the infrared portion is used.

### TECHNICAL FIELD

The present disclosure relates to a camera system for a vehicle. More particularly, the present disclosure relates to a surround view camera system with improved low light performance.

### BACKGROUND OF THE DISCLOSURE

Present automotive vehicles may utilize camera systems to assist vehicle drivers during use of the vehicle. These camera systems may be used to passively assist the driver during a driver actuated and controlled maneuver, and they may also be used as part of a driver-assist system, where the vehicle may provide controls to the vehicle.

For example, a camera system may be used to display the rear area of the vehicle when the vehicle is engaged in a reversing maneuver, when visibility behind the vehicle may be difficult. Camera systems may also be used to detect obstacles in the roadway, such as other vehicle, pedestrians, animals, or the like, and may be used to assist in braking the vehicle or maneuvering the vehicle to avoid or limit an imminent collision.

Similarly, the camera systems may be used to detect vehicles present in a blind spot of the vehicle, and may be used with a vehicle control system to provide a warning to the driver.

Cameras are also in use with autonomous driving systems, in which the systems are configured to view and monitor the vehicle surroundings to determine what type of vehicle maneuver to perform. Autonomous driving systems and advanced driver assist systems (ADAS) may also utilize radar to detect the presence of certain objects relative to the vehicle, but the radar systems are limited in what they can reliably detect. For example, radar may provide accurate velocity and distance information of an object outside of the vehicle, but is not as accurate as a camera in determining and classifying what the object is.

Camera systems therefore are used to reproduce the environment that is typically viewable by the human eye. Cameras are useful when there is ample light present in the environment, but the performance capabilities of cameras decreases dramatically at night and can be almost unusable in extreme low light conditions.

In some cases, the forward facing headlights typical in vehicles can provide sufficient illumination at night or in extreme low light conditions. Similarly, the tail lights and reverse-lighting that occurs during reverse vehicle maneuvers can also provide light at the rear of the vehicle sufficient for minor reverse maneuvers. However, side cameras do not benefit from headlights or tail lights to illuminate the environment.

In view of the foregoing, there remains a need for improvements to camera systems in vehicles.

### SUMMARY OF THE INVENTION

A system for processing images from a camera for a vehicle is provided. The system may include a camera module including a lens configured to receive light from a surrounding environment, the camera module including a camera sensor disposed adjacent the lens and configured for receiving light that passes through the lens, an image signal processor operatively coupled to the camera module and configured to receive data from the camera sensor, and a control unit operatively coupled to the image signal processor and configured to receive an image from the image signal processor.

The system may further include an infrared light elimination mechanism associated with the camera sensor and operable in a normal light condition for eliminating an infrared portion of the light that passes through the lens, and further operable in a low light condition for allowing the infrared portion of the light passing through the lens to be processed by the image signal processor.

In another aspect, a method for capturing and processing an image in a camera system for a vehicle is provided. The method includes the step of receiving light into a camera module through a lens, wherein at least a portion of the light passes to and is received at a camera sensor coupled to an image signal processor and an autonomous driving control unit.

The method further includes detecting a normal light condition in an environment surrounding the vehicle and eliminating an infrared portion of the light received through the lens in response to detecting the normal light condition to define a non-infrared light portion. The method further includes using the non-infrared light portion to define and process a normal-light image for use in the control unit.

The method further includes detecting a low light condition in an environment surrounding the vehicle and using all of the light that passes through the lens in response to detecting the low light condition to define and process a low-light image for use in the control unit.

### A BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 illustrates one aspect of a camera system including at least one infrared illuminator and an RGB-IR sensor for capturing light in both a low light and a normal light condition;

FIG. 2 illustrates another aspect of the camera system including an RGB sensor and an IR-cut filter disposed in an unfiltered position for allowing all of the light passing through a lens to reach to the RGB sensor;

FIG. 3 illustrates the system of FIG. 2, illustrating the IR-cut filter disposed in a filtered positon for blocking an infrared portion of the light passing through the lens from reaching the RGB sensor; and

FIG. 4 illustrates camera modules and illuminators disposed at multiple locations on a vehicle.

### DESCRIPTION OF THE ENABLING EMBODIMENTS

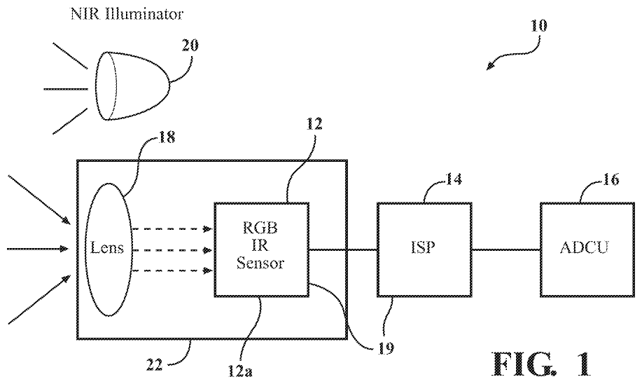

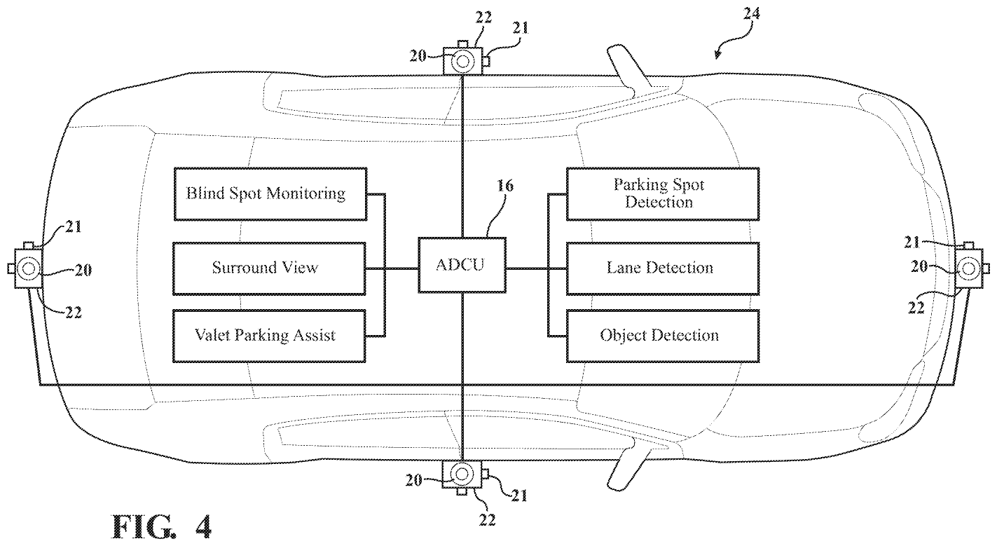

Referring to FIGS. 1-4, a camera system 10 for use in a vehicle 24 (shown in FIG. 4) is provided. The system 10 may include a camera sensor 12, an image signal processor (ISP) 14, an Autonomous Driving Control Unit (ADCU) 16, a camera lens 18, and an infrared illuminator 20. The system may further include an infrared elimination mechanism 19, which is further described below. The infrared elimination mechanism 19 is configured to eliminate an infrared portion of light that passes through the lens 18. During “normal” daytime operation, the ADCU 16 determines that environmental light is sufficient to illuminate the surroundings of the vehicle, the illuminator 20 is turned off by the ADCU 16, and raw pixel data is collected by the sensor 12 and ISP 14 for further processing by the ADCU 16, such as for machine learning or other applications. The infrared elimination mechanism 19 may be used during the normal light condition such that an image resembling what the human eye can see is used by the ADCU 16. During low-light or nighttime operation, the ADCU 16 determines that the environmental light is limited, and thus the ADCU 16 turns on the illuminator 20, and near IR data is collected by the sensor 12 and ISP 14 for further processing by the ADCU 16. The infrared elimination mechanism 19 is typically not used during the low light condition, because the extra light is desirable to produce an image for processing by the ADCU 16.

The sensor 12 may be in the form of a CMOS or CCD camera sensor. The sensor 12 may typically pick up more light than the human eye. This extra light that that the sensor 12 picks up is in the near infrared band that human eyes cannot see. For camera systems to produce “normal” looking images during daytime operation or the like, relative to the human eye, the system 10 may eliminate or reduce the “extra light” that may be collected by the sensor 12. In the low-light condition, representing color correctly for the human eye is less relevant, and therefore it is advantageous for the sensor 12 to pick up the extra light to aid the sensor 12 and ISP 14 to produce a usable image for the ADCU 16 to process.

With reference to FIG. 4, the system 10 may include a number of camera modules 22 that are mounted at different locations of the vehicle 24. In one approach, four camera modules 22 are installed on the vehicle 24, with one being disposed at the front, one at the rear, and one on each lateral side of the vehicle 24. The camera modules 22 may each include one of the sensors 12 and one of the lenses 18, and are associated with one of the ISPs 14 and one of the illuminators 20. The ISP 14 may also be included as part of the camera module 22. The illuminator 20 may also be included as part of the camera module 22. The camera modules 22 may be operatively connected, such as via wire harness or the like, to the ADCU 16, which may be disposed inside of the vehicle 24. Alternatively, a common ISP 14 may be used in the system 10 that communicates with more than one of the sensors 12 and modules 22 of the system 10, such that the module 22 may not include a dedicated ISP. Furthermore, while the system 10 has been described as having illuminators 20 at each of the modules 22, multiple illuminators 20 may be disposed or associated with each of the modules 22. For purposes of further discussion, a single illuminator 20 will be described, but it will be appreciated that the reference to the illuminator 20 may also refer to multiple illuminators at a given camera module 22. The ADCU 16 may communicate with the camera unit 22 to collect sensor data and may communicate with the illuminator 20 to turn on/off the illuminator 20.

In one approach, and with reference to FIG. 1, the sensor 12 is in the form of a RGB-IR sensor 12a. The infrared elimination mechanism 19 in this approach may comprise software in the system 10 that will ignore, subtract, or eliminate an IR portion of light received at the sensor 12a due to the composition of pixels in the RGB-IR sensor. The RGB-IR sensor 12a includes an array of pixels arranged on a substrate in a manner known in the art. Individual pixels of the RGB-IR sensor 12a include dedicated Red pixels (R), Green pixels (G), Blue pixels (B), and IR pixels (IR). Thus, the sensor 12a may receive an RGB component of the light received at the sensor (when the R, G, and B pixels are combined) as well as an IR component. Light received at the sensor 12a, including both light that the human eye can detect received in the RGB portions of the sensor as well as light that the human eye cannot detect in the IR portions of the sensor 12a, can be received by the ISP 14 and ultimately at the ADCU 16.

Light is received at the sensor 12a after passing through the lens 18, which focuses the incoming light at the camera module 22 and in particular the light passing through the lens 18 onto the sensor 12a. The lens 18 may be selected from a group of lens that are specifically designed to work with the RGB-IR type sensor 12a.

In the system 10 that uses the RGB-IR sensor 12a, all of the light passing through the lens 20 is received by the sensor 12a and all or a portion of the received light, in the form of pixel data at the various pixels, can be processed further by the ISP 14 and the ADCU 16. Whether or not all of the data is used by the ADCU 16 depends on whether the camera unit 22 is operating in the normal light condition or the low-light condition.

In the normal light condition, if all of the received data from the pixels of the sensor 12a were used by the ADCU 16, the resulting image would include too much extra light, because of the data received by the IR pixels. The resulting image would appear in a manner that does not represent what a human eye perceives, thereby creating an inaccurate image for the ADCU 16 to use in its machine learning processes, and further creating an image that when viewed by the human eye is distorted If the IR portion is not subtracted during a normal light condition, the resulting image may include a magenta-type tint, and the image would therefore not be desirable for backup camera views, side camera views, or the like. Typically, ADCUs and machine learning processes operate based on “normal” looking images that resemble what the human eye can perceive, but the images may also be used for real time visual monitoring by the vehicle driver or occupants.

Thus, during a normal light condition, the IR data is preferably removed. In the normal light condition, the ADCU 16 turns off the illuminator 20, and the raw data received in the camera unit 22 includes both the RGB and IR data collected by the pixels of the sensor 12a. Software present in the ISP 14 or the ADCU 16 may then subtract, remove, or delete the IR data, leaving only the data from the RGB pixels. The IR pixels on the sensor 12a are in a predetermined layout, and therefore the system 10 is aware of exactly which pixels and data to remove from the raw data to leave only the RGB data in order to construct an image that conforms to what the human eye typically perceives at normal light conditions.

As described above, in the normal light operation, the illuminator 20 is turned off, because the IR data that is received by the sensor 12a is intended to be deleted from the image. However, the ADCU 16 could alternatively turn on the illuminator 20, which may increase the amount of IR data that is received by the IR pixels of the sensor 12a. The system may operate in the same manner described above, in which the increased IR data is removed, leaving only the RGB data. Thus, even if more IR data is collected, the increased IR data as a result of the illuminator 20 being on is deleted.

In a low light condition, the ADCU 16 turns on the illuminator 20, which illuminates the near IR light in the environment around the camera unit 22. The illuminated light, including near-IR light, passes through the lens 18 and is received by the RBG-IR sensor 12a. The raw data received at the sensor 12a includes the raw RGB data from the RBG pixels, as well as the raw IR data from the IR pixels. The raw data does not need to have the data from the IR pixels subtracted, because the data from the IR pixels is desirable in low light conditions in order to produce a usable image for the ADCU 16. This is the case because even with the illuminator 20 on, the data from the RGB pixels is reduced relative to a normal light condition. The RGB-IR sensor 12a therefore provides an improved image for the ADCU 16 to use in machine learning applications.

The system 10 using the RGB-IR sensor 12a may include additional light sensors 21 (shown in FIG. 4) that communicate with the ADCU 16 and determine the light condition of the environment. The additional light sensors 21 may operate to detect a threshold level of light, and if the light is below the threshold level, the ADCU 16 may determine that the low light condition is present. If the light is above the threshold level, the ADCU 16 may determine that the normal light condition is present.

The ADCU 16 may operate in response to detecting the low light condition or the normal light condition by sending various signals within the system 10 that may control connected components. For example, the ADCU 16 may send a signal to the illuminator 20 to turn the illuminator 20 off in response to detecting a normal light condition when the light is above the threshold level. The ADCU 16 may also send a signal to the illuminator 20 to turn the illuminator 20 on in response to detecting a low light condition when the light is below the threshold level.

The ADCU 16 may similarly send a signal to the ISP 14 to delete the IR pixel data from the raw data of the sensor 12a in response to determining a normal light condition when the light is above the threshold level. The ADCU 16 may send a signal to the ISP 14 to use all of the raw data in response to determining a low light condition when the light is below the threshold level.

The above system 10 with the RGB-IR sensor 12a can therefore collect data in both the low light and normal light conditions. The data used by the ADCU 16 is either the entire raw data during low light conditions, or just the RGB data in normal conditions, with the IR portion having been subtracted from the raw data.

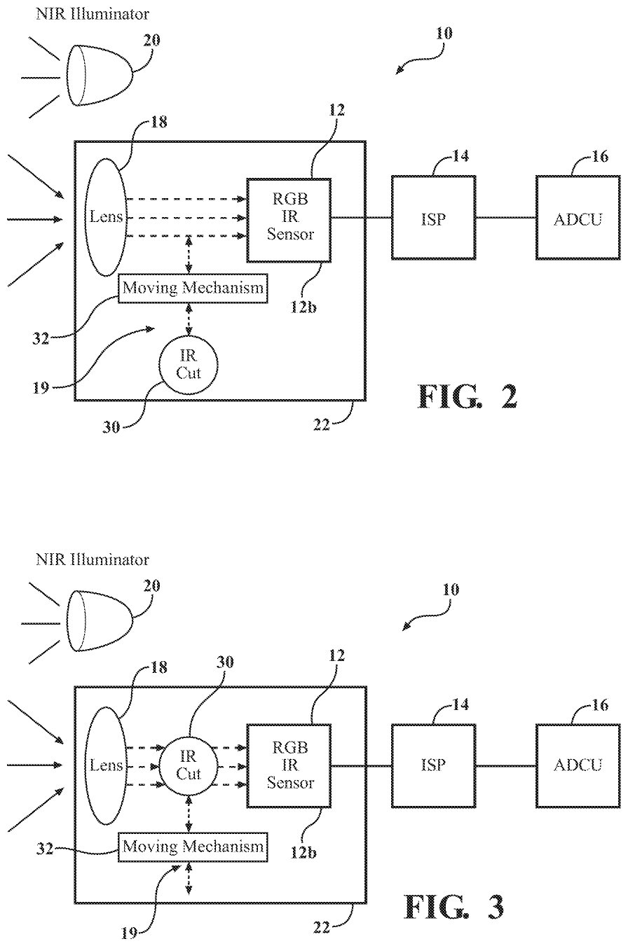

In another approach, and with reference to FIGS. 2 and 3, the sensor 12 may be a RGB sensor 12b. The RGB sensor 12b differs from the RGB-IR sensor 12a in that the RGB sensor 12b does not include pixels dedicated to receiving IR light. Rather, the RGB pixels will detect the IR light.

The system 10 may further include an IR-cut filter 30. In this approach, the infrared elimination mechanism 19 comprises the IR-cut filter 30. The IR-cut filter 30 may be installed within the camera module 22, along with the lens 18 and the RGB sensor 12b. The IR-cut filter 30 may be connected to a moving mechanism 32 configured to move the IR-cut filter 30 between at least two different positions. The moving mechanism 32 may be a mechanically actuatable mechanism to which the IR-cut filter 30 is attached, with the mechanism 32 being actuated to move the filter 30 along a path between filtering and non-filtering positions. For example, a motor and a rotation-translation mechanism may be used or a solenoid actuator may be used. Other types of controllable mechanisms that may actuate in response to a control signal may be used.

In a first position of the IR-cut filter 30, shown in FIG. 3, the filter 30 is disposed between the lens 18 and the sensor 12a. In the second position of the IR-cut filter 30, shown in FIG. 2, the filter 30 is disposed in a position away from the lens 18 and the sensor 12b. In the first position, light passing through the lens 18 will also pass through the IR-cut filter 30 prior to reaching the sensor 12b. In the second position, light passing through the lens 18 will reach the sensor 12b without having passed through the IR-cut filter 30, such that the IR-cut filter 30 is bypassed. The first position may be referred to as the filtered position for use in a normal light condition and the second position may be referred to as the unfiltered or non-filtered position for use in a low light condition.

The IR-cut filter 30 is configured to block IR light, such that the light passing through the IR-cut filter 30 that reaches the sensor is effectively limited to the band of light visible to the human eye. With the IR-cut filter 30 being moveable between the first and second position, the system 10 can control whether or not IR light is detected by the sensor based on the position of the IR-cut filter relative to the lens 18 and the sensor 12b.

In a normal light condition, in which sufficient light is present to enable machine learning applications based on images resembling those visible to the human eye, the IR-cut filter 30 may be moved to the first position, shown in FIG. 3. Thus, any light passing through the lens 18, including IR light, will also pass to the IR-cut filter 30. The IR-cut filter 30 will block the IR portion of the light that enters the camera unit 22. The RGB sensor 12b will therefore receive a light input that does not include the IR portion of the light that is blocked by the IR-cut filter 30.

Thus, the raw data collected by the sensor 12b may be passed on to the ADCU 16 without any special processing, aside from traditional image processing that converts RGB pixels to images. The ADCU 16 may then process the image using machine learning applications and models as necessary.

In the normal light condition, the IR illuminator 20 may be turned off by the ADCU 16, because the IR light passing through the lens 18 will nevertheless be filtered out by the IR-cut filter 30, so additional illumination for IR light is generally unnecessary. Thus, any additional IR light that is illuminated by the IR illuminator 20 would not pass to the RGB sensor 12b. However, it will be appreciated that the IR illuminator 20 may be turned on by the ADCU 16, even in normal light conditions, and the system 10 may operate in the same manner, with the raw data collected at the sensor 12b being used without any special processing to remove an IR portion, because the IR light is blocked by the filter 30.

In the low light condition, it is desirable to collect the extra light from the IR band. Accordingly, in the low light condition, the IR-cut filter 30 may be moved out of the path between the lens 18 and the sensor 12b, as shown in FIG. 2. With the IR-cut filter 30 moved out of the path, IR light passing through the lens 18 will reach the sensor 12b.

As illustrated in FIG. 4, the system 10 using the RGB sensor 12b may include the light sensors 21 that communicate with the ADCU 16 and determine the light condition of the environment. The additional sensors 21 may operate to detect a threshold level of light, and if the light is below the threshold level, the ADCU 16 may determine that the low light condition is present. If the light is above the threshold level, the ADCU 16 may determine that the normal light condition is present.

The ADCU 16 may operate in response to detecting the low light condition or the normal light condition by sending various signals within the system 10 that may control connected components. For example, the ADCU 16 may send a signal to the illuminator 20 to turn the illuminator 20 off in response to detecting a normal light condition when the light is above the threshold level. The ADCU 16 may also send a signal to the illuminator 20 to turn the illuminator 20 on in response to detecting a low light condition when the light is below the threshold level.

Similarly, the ADCU 16 may send a signal to the moving mechanism 32 coupled to the filter 30 in response to determining a normal light condition when the light is above the threshold level, with the signal controlling the moving mechanism 32 to move the filter 30 into the first position where the filter 30 is disposed between the lens 18 and the RGB sensor 12a. The ADCU 16 may send a signal to the moving mechanism 32 in response to determining a low light condition when the light is below the threshold level to move the filter 30 out of the light path between the lens 18 and the RGB sensor 12b and into the second position, so that the IR light may be collected by the RGB sensor 12b.

In the low light condition, and in order to increase the amount of extra light collected, the IR illuminator 20 may be turned on, thereby providing IR light nearby, which can be collected by the RGB sensor 12b. With the IR-cut filter 30 moved out of the path between the lens 18 and the sensor 12b, the extra illuminated IR light is not blocked.

In the low light condition with the IR illuminator 20 on and the IR-cut filter 30 moved out of the path between the lens 18 and the sensor 12b, the raw data collected by the sensor 12b is used by the ADCU 16 without special processing to remove an IR portion of the image.

The camera module 22 with the movable IR-cut filter 30 therefore allows a single camera module to be used during both low light and normal light conditions. This solution provides efficiencies relative to systems that use separate camera modules, where one camera module has an IR-cut filter in a fixed position and is used to collect the light during normal light conditions, and another camera module is without an IR-cut filter and is used to collect the light during low light conditions.

It will be appreciated that some of the features described above may be used in combination with each other.

In one approach, the RGB-IR sensor 12a may be used, along with the IR-cut filter 30. In this approach, the IR-cut filter 30 may be moved to the first position to block IR light from reaching the RGB-IR sensor 12a. Thus, the system 10 may operate without subtracting the data from the IR pixels, because the IR-cut filter 30 blocks the IR light. The raw data may still include an IR component, but the IR component would effectively be empty, and therefore could remain as part of the raw data. Alternatively, the system 10 may still operate in the same manner as the RGB-IR sensor system previously described above, with the IR component deleted or subtracted from the raw data, if desired.

Similarly, the IR-cut filter 30 may be moved to the second unfiltered position even in the normal light operation. In this case, the system 10 would operate as described above with respect to the RGB-IR sensor 12a, in which the IR component is subtracted, because the IR-cut filter 30 was moved out into its second position and did not block IR light.

Basically, the system can include the IR-cut filter 30 with a RGB-IR sensor 12a. When the IR-cut filter 30 is in the second unfiltered position, the system 10 operates similarly to the RGB-IR system previously described.

The primary differences between the system 10 with the RGB sensor 12b plus the IR-cut filter 30 and the system 10 with the RGB-IR sensor 12a without an IR-cut filter is the manner in which the normal light condition is handled and processed. With the RGB sensor 12b and IR-cut filter 30, the filter 30 optically removes the IR light from reaching the RGB sensor, such that the light that is received is effectively limited to the band that the human eye can detect.

With the RGB-IR sensor 12a and no IR-cut filter, the IR light will reach the sensor 12a and be collected by the sensor 12a. However, the dedicated IR pixels will effectively compartmentalize the IR portion of the image, which can then be removed via software, because the software knows which pixel data is from the IR band.

In both cases, the IR portion of an image is removed from the resulting image. The difference is whether the IR portion is blocked at the front end optically or at the back end via software.

Both of these systems operate in a similar manner in the low light condition. In each case, there is no optical blocking of IR light, because the IR-cut filter 30 is either not present in the system or is moved to its second position out of the path between the lens 18 and the sensor 12a/12b. Thus, in each case, the full spectrum of light entering the camera is collected by the sensor, and the raw data is used by the system, with the extra IR light providing a usable image for the machine learning applications and models of the ADCU 16.

Obviously, many modifications and variations of the present invention are possible in light of the above teachings and may be practiced otherwise than as specifically described while within the scope of the appended claims. These antecedent recitations should be interpreted to cover any combination in which the inventive novelty exercises its utility.

What is claimed is:

1. A system for processing images from a camera for a vehicle, the system comprising:
a camera module including a lens configured to receive light from a surrounding environment;
the camera module including a camera sensor disposed adjacent the lens and configured for receiving light that passes through the lens;
an image signal processor operatively coupled to the camera module and configured to receive data from the camera sensor;
a control unit operatively coupled to the image signal processor and configured to receive an image from the image signal processor;
an infrared light elimination mechanism associated with the camera sensor and operable in a normal light condition for eliminating an infrared portion of the light that passes through the lens, and further operable in a low light condition for allowing the infrared portion of the light passing through the lens to be processed by the image signal processor.

2. The system of claim 1, further comprising a least one infrared illuminator associated with the camera module for providing near infrared illumination to the surrounding environment.

3. The system of claim 2, wherein said control unit is configured to turn on the at least one illuminator in the low light condition and turn off the at least one illuminator in the normal light condition.

4. The system of claim 2, wherein the camera sensor is an RGB-IR sensor having a plurality of IR pixels dedicated to receiving the infrared portion of the light.

5. The system of claim 4, wherein the infrared elimination mechanism comprises software associated with the image signal processor and configured to evaluate data from the IR pixels of the RGB-IR sensor in the low light condition and ignore the data from the IR pixels in the low light condition.

6. The system of claim 2, wherein the camera sensor is an RGB sensor.

7. The system of claim 6, wherein the infrared elimination mechanism comprises an IR-cut filter configured to block infrared light passing through the lens from reaching the RGB sensor.

8. The system of claim 7, wherein the IR-cut filter is disposed within the camera module and moveable from the low light condition wherein the IR-cut filter is disposed outside of a path between the lens and the RGB sensor to the normal light condition wherein the IR-cut filter is disposed between the lens and the RGB sensor.

9. The system of claim 8, further comprising a moving mechanism coupled to the IR-cut filter, wherein the moving mechanism is actuated to move the filter between the low light condition and the normal light condition.

10. The system of claim 2, wherein in the low light condition the image signal processor uses raw data from the camera sensor to define an image.

11. The system of claim 10, wherein in the normal light condition, the image signal processor deletes an infrared portion of the raw data from the camera sensor.

12. The system of claim 10, wherein in the normal light condition, the image signal processor uses raw data from the camera sensor.

13. The system of claim 12, wherein in the normal light condition, the raw data from the camera sensor does not include an infrared portion.

14. A method for capturing and processing an image in a camera system for a vehicle, the method comprising the steps of:
receiving light into a camera module through a lens, wherein at least a portion of the light passes to and is received at a camera sensor coupled to an image signal processor and an autonomous driving control unit;
detecting a normal light condition in an environment surrounding the vehicle;
eliminating an infrared portion of the light received through the lens in response to detecting the normal light condition to define a non-infrared light portion and using the non-infrared light portion to define and process a normal-light image for use in the control unit;
detecting a low light condition in an environment surrounding the vehicle;
using all of the light that passes through the lens in response to detecting the low light condition to define and process a low-light image for use in the control unit.

15. The method of claim 1 further comprising activating at least one infrared illuminator in response to detecting the low light condition for illuminating the environment surrounding the vehicle.

16. The method of claim 15 further using raw data received at the camera sensor comprising in response to detecting the low light condition to define and process the low light image.

17. The method of claim 15, wherein the camera sensor is an RGB-IR sensor, and all of the light passing through the lens is received at the RGB-IR sensor in both the low light condition and the normal light condition.

18. The method of claim 17 wherein the step of eliminating an infrared portion includes ignoring the infrared portion from raw data received from the RGB-IR sensor.

19. The method of claim 15, wherein the camera sensor is an RGB sensor, and the camera module includes an IR-cut filter moveable from a filtered position disposed between the lens and the RGB sensor to an unfiltered position where the filter is disposed outside of a path defined between the lens and the camera sensor.

20. The method of claim 19, wherein the step of eliminating an infrared portion includes moving the IR-cut filter to the filtered position and blocking the infrared portion from reaching the RGB sensor.
